(19) United States
(12) Patent Application Publication
(10) Pub. No.: US 2021/0265090 A1
(43) Pub. Date: Aug. 26, 2021

(54) SOLENOID DITHER CONTROL SYSTEM AND METHOD

(71) Applicant: SEMICONDUCTOR COMPONENTS INDUSTRIES, LLC, Phoenix, AZ (US)

(72) Inventor: Bart DE COCK, Wespelaar (BE)

(73) Assignee: SEMICONDUCTOR COMPONENTS INDUSTRIES, LLC, Phoenix, AZ (US)

(21) Appl. No.: 16/800,117

(22) Filed: Feb. 25, 2020

(51) Int. Cl. H01F 7/06; H01F 7/08; H03K 3/017

(52) U.S. Cl. CPC H01F 7/064; H03K 3/017; H01F 7/081

(57) ABSTRACT

Improved solenoid controllers and control methods. One illustrative solenoid control method embodiment includes: supplying a drive signal to a solenoid, the drive signal having: an average current corresponding to a desired position of an armature, and a dither current having a dither amplitude that produces an associated solenoid voltage variation; varying the dither amplitude in a region insufficient to overcome static friction of the armature; determining a linear relationship between the dither amplitude and the associated solenoid voltage variation in said region; increasing the dither amplitude while monitoring the associated solenoid voltage variation for a deviation below the voltage variation indicated by the linear relationship; and upon detecting said deviation, employing a corresponding dither amplitude to maintain mobility of the armature.

### FIELD

The present invention relates to a method for controlling a solenoid. The disclosure relates specifically to a method to obtain information on the physical movement of an armature of the solenoid.

### BACKGROUND

A solenoid is an electromagnet combined with an actuator to convert electrical energy into linear physical motion. A solenoid may typically include a coil conductor wrapped around a metallic piston that serves as an armature. When voltage is applied to the coil terminals, current is passed through the coil conductor generating an electromagnetic field, which draws the metallic piston toward the field. An electronic controller may be coupled to the solenoid for regulating the flow of current through the coil conductor to control the electromagnetic field. Solenoids can be used in a wide range of devices and applications. They can be used to electrically open doors and latches, open or close valves, move and operate robotic limbs and mechanisms, and even actuate electrical switches.

Traditional solenoid driver electronics rely on linear current, which is the application of a constant voltage across a resistance to produce an output current that is directly proportional to the voltage. Feedback can be used to achieve an output that exactly matches the control signal. However, this scheme dissipates a lot of power as heat, and it is therefore very inefficient. This heat can cause overheating the solenoid coil to a point where its operation becomes unstable and may even result in either malfunction or no function. Solenoid coils lose their force power when overheated.

Two improved solenoid control techniques include Pulse Width Modulation (PWM) and Dither. Pulse width modulation produces a desired average current through the coil by controlling the amount of time the cyclic PWM signal is “on” versus the amount of time it is “off”. This duty cycle can vary as compared to the input signal and produces a much more effective means to control proportional control valves.

However, even with PWM, static friction (“stiction”) and hysteresis can cause the control of a valve to be erratic and unpredictable. Stiction can prevent the armature from moving when given small input changes, and hysteresis can cause the shift to be different for different applications of the same input signal. In order to counteract the effects of stiction and hysteresis, small cyclic current amplitude vibrations (a dither) around the desired average current are created in the solenoid. This dither constantly overcomes the static friction ensuring that the armature will move even with small input changes, and the effects of hysteresis are averaged out. Dither can be provided as a small ripple that is superimposed on the control signal for the PWM solenoid current that causes the desired vibration and thereby increases the linearity of the valve and improves valve response.

Dither and PWM frequencies complement each other for improved control and are, in most cases, adjustable independently. This allows the user to customize these signals to each individual application for optimum performance. Low frequency PWM, typically less than 400 Hz, can generate dither or current ripple as a byproduct of the PWM process. The amount of dither is not constant and is changed as the average coil current changes. This can result in too much dither at some current levels and not enough at others. Further, this kind of dither is reliant on PWM duty cycle and PWM frequency, and its amplitude and frequency cannot be set independently. It is not ideal for many valve designs that require a specific setting of dither. For high PWM frequency, the coil current does not have ripple. No byproduct dither is produced. Therefore, high frequency PWM, which is often used to eliminate undesirable internal dither, may be augmented by an adjustable external dither. The essence of generating dither is to change the duty cycle of the PWM output waveform at a certain frequency; changing the duty cycle of the PWM can change dither amplitude and frequency applied to the solenoid.

If dither amplitude is too small, then static friction is not removed and the control system cannot provide smooth control, potentially causing safety issues. If dither amplitude is too large, then energy is wasted and the solenoid wears out too early. Therefore, the dither amplitude should be adjusted such that the armature is only moving slightly.

In order to provide appropriate dithering current to the solenoid, it is known to detect the movement of the armature, and based on the detection, a dithering current is applied to the solenoid to move the armature slightly. An example of such a method is described in WO2018233917 to Berger et al. which was published on Dec. 27, 2018. Berger et al. teaches a dither control loop in which solenoid voltage V and/or solenoid current I is observed to generate a “coil signal”, a calculator uses a physical model of the solenoid to find speed of the armature, the speed is further analyzed to extract a movement parameter. Although there is no need of a sensor to detect the movement of the armature, it requires a high-speed communication interface from an ASIC to a microcontroller and large calculation overhead in the microcontroller because of complicated calculating solenoid model.

There are other methods and algorithms available to detect the movement of armature in solenoids. For example, US2010/0087999 to Neelakantan et al. published on Apr. 8, 2010 discloses a method for detecting end-of fill for a hydraulic clutch with a variable force solenoid. Neelakantan et al. teach looking for increased pressure evidenced by an aberration in the current.

US2007/0279047 to Schumacher published on Dec. 6, 2007 provides a method for detecting solenoid armature movement. Schumacher uses hysteretic current control and observes a time variation when the solenoid pulls in. The method detects a large movement of the armature to control an on/off event.

The existing systems and methods fail to offer a sufficiently low-complexity method for detecting the physical movement of the armature for efficient solenoid control.

### SUMMARY

Accordingly, there are disclosed herein improved solenoid controllers and control methods. One illustrative solenoid control method embodiment includes: supplying a drive signal to a solenoid, the drive signal having: an average current corresponding to a desired position of an armature, and a dither current having a dither amplitude that produces an associated solenoid voltage variation; varying the dither amplitude in a region insufficient to overcome static friction of the armature; determining a linear relationship between the dither amplitude and the associated solenoid voltage variation in said region; increasing the dither amplitude while monitoring the associated solenoid voltage variation for a deviation below the voltage variation indicated by the linear relationship; and upon detecting said deviation, employing a corresponding dither amplitude to maintain mobility of the armature.

An illustrative embodiment of a solenoid controller includes: a PWM (pulse width modulation) driver that supplies a drive signal to a solenoid, and a processor that implements the control method outlined above.

Each of the foregoing embodiments may be implemented individually or in combination, and may be implemented with any one or more of the following features in any suitable combination: 1. said drive signal is provided using PWM (pulse width modulation) at a PWM frequency. 2. said dither frequency is less than the PWM frequency and a period of the dither current includes multiple PWM periods. 3. said determining includes, for each of multiple dither amplitude values: obtaining an average solenoid voltage for each PWM period in at least one period of the dither current; and calculating said associated solenoid voltage variation based on a difference between a maximum and a minimum of the average solenoid voltages in the at least one period. 4. a calculation frequency is less than the PWM frequency and a calculation period includes multiple PWM periods. 5. said determining includes, for each of multiple dither amplitude values: obtaining a baseline average solenoid voltage for a first calculation period; obtaining for each PWM period in a subsequent calculation period an absolute value of a difference between the baseline average and an average solenoid voltage for that PWM period; and calculating said associated solenoid voltage variation as an average of said absolute values. 6. the dither current has a triangular waveform. 7. indicating that the armature is blocked if the dither amplitude reaches a predetermined threshold without detection of said deviation. 8. repeating said varying, determining, and increasing operations each time the desired position changes. 9. the PWM driver supplies the drive signal via a switching element that selectively couples the solenoid coil to a power supply. 10. the controller further includes a voltage sensor to detect the solenoid voltage. 11. a current sensor for the drive signal to provide closed-loop feedback control. 12. each period of the dither current including less than two PWM periods. 13. the processor performs said determining using a calculation period that includes multiple PWM periods. 14. the controller is implemented as an integrated circuit module.

The system has the potential to save energy and to improve all-over quality and reliability of solenoid products.

The foregoing has outlined rather broadly the features of the present disclosure in order that the detailed description that follows may be better understood. Additional features and advantages of the disclosure will be described hereinafter, which form the subject of the claims.

### BRIEF DESCRIPTION OF THE DRAWINGS

In order that the manner in which the above-recited and other enhancements and objects of the disclosure are obtained, a more particular description of the disclosure briefly described above will be rendered by reference to specific embodiments thereof which are illustrated in the appended drawings. Understanding that these drawings depict only typical embodiments of the disclosure and are therefore not to be considered limiting of its scope, the disclosure will be described with additional specificity and detail through the use of the accompanying drawings in which:

FIG. 1 is a structural diagram of a solenoid of prior art.

FIG. 2 is a schematic diagram of a system for detecting micro-movement of an armature in accordance with one embodiment of the present invention.

FIG. 3 is a voltage waveform of a solenoid corresponding to a set DC solenoid input current and an AC dither current.

FIG. 4 is a schematic diagram of calculating the detection index voltage in accordance with one embodiment of the present invention.

FIG. 5 is a schematic diagram showing the relationship between the dither amplitude I and Vpp.

FIG. 6 is a schematic diagram showing the relationship between the dither amplitude I and Vac.

FIG. 7 is a schematic diagram showing the relationship between the dither amplitude I and Vpp when the armature is blocked.

FIG. 8 is a schematic diagram showing the relationship between the dither amplitude I and Vac when the armature is blocked.

FIG. 9 is a schematic diagram of calculating the detection index voltage when the period of the dither is equal to that of a PWM.

FIG. 10 is a schematic diagram showing the—detection index voltage in different load conditions.

### DETAILED DESCRIPTION

The particulars shown herein are by way of example and for purposes of illustrative discussion of the preferred embodiments of the present disclosure only and are presented in the cause of providing what is believed to be the most useful and readily understood description of the principles and conceptual aspects of various embodiments of the disclosure. In this regard, no attempt is made to show structural details of the disclosure in more detail than is necessary for the fundamental understanding of the disclosure, the description taken with the drawings making apparent to those skilled in the art how the several forms of the disclosure may be embodied in practice.

FIG. 1 is a structural diagram of an exemplary solenoid 10 according to certain disclosed embodiments. The solenoid 10 may include an electromechanical transducer to convert electrical energy to linear momentum for actuating at least one mechanical device associated with the solenoid 10. For example, solenoid 10 may be configured as an electromechanical valve, relay, switch, or other suitable device that may be configured to provide mechanical output power based on an electrical power input. For example, solenoid 10 may include one or more valves configured to regulate the flow of fuel to a combustion chamber.

The solenoid 10 includes a solenoid coil 16 selectively coupled to magnetically drive an armature 11 and to release armature 11. Solenoid coil 16 may include any type of metallic conductor and may be configured in a substantially coiled arrangement. This coiled arrangement may facilitate the induction of an electromagnetic field substantially around the coil, with the strongest field contained within the area associated with a perimeter created by the coil. Solenoid coil may include copper, aluminum, steel, nickel, iron or any other suitable metallic or metallic-alloy wire that may be used to induce a magnetic field associated with a passage of current through the wire.

Armature 11 may be disposed substantially coaxially within the coil 16 and configured to move relative to solenoid coil 16 in the presence of an electromagnetic field generated by a current passing through the coil. Movement of armature 11 may be proportional to the strength of the electromagnetic field. Armature 11 may be constructed of any high magnetic permeability material such as, for example, iron, nickel, cobalt, or any other suitable high-permeability metal or metal-alloy.

In order to enhance the strength of the electromagnetic field in the solenoid coil 16, the solenoid 10 may include an iron core 12 at a fixed position within and coaxial to the coil 16. The iron core 12 is on the opposite side of the armature 11 and separated from the armature 11 via an air gap 14. The iron core 12 may be constructed of any high magnetic permeability material such as iron, nickel, cobalt, or any other suitable high-permeability metal or metal-alloy. There is a spring 15 which urges the armature 11 away from the iron core 12. When the coil 16 is not energized, the spring pushes the armature away from the iron core 12. When the coil 16 is energized by a current of sufficient strength to move the armature 11 against the pressure of the spring 15 to close to the iron core 12 until the pressure of the spring 15 balances the magnetic force on the armature 11.

The solenoid coil 16, armature 11, air gap 14 and iron core 12 constitute a magnetic circuit with time varying inductance but constant resistance as shown in FIG. 1. The magnetic field, through the air gap 14, exerts an attractive force on the armature 11 to pull it close to the iron core 12. According to Kirchhoff's law of voltage, the voltage applied to the coil is equal to the summation of voltage drop across the equivalent coil resistance and the electromotive potential caused by changes in magnetic flux linkage.

A simplified electrical equation of a solenoid can be written as:

$$U = {R}_{0} i + \frac{d ψ}{dt} = {R}_{0} i + \frac{\partial ψ}{\partial i} \frac{d i}{dt} + \frac{\partial ψ}{\partial δ} \frac{d δ}{dt} \qquad ( 1 )$$

where U is the applied voltage, i is the current in the coil, δ is the length of solenoid's air gap 14, R₀ is the coil resistance and ψ is the flux linkage. The R₀i represents the resistive drop and the

$$\frac{d ψ}{dt}$$

is the induced voltage. The inductance of the coil depends on the position of the armature 11 since the magnetic reluctance of the solenoid depends on the armature position (since the armature's reciprocating motion creates a variable width air gap, the inductance of the solenoid fluctuates). Therefore the flux linkage in the coil depends on the current in the coil and the position of the armature 11.

$$\frac{\partial ψ}{\partial i}$$

is the inductance of the solenoid,

$$\frac{\partial ψ}{\partial i} \frac{d i}{dt}$$

is the voltage drop due

$$\frac{\partial ψ}{\partial δ} \frac{d δ}{dt}$$

to change in current, and (electromotive force), a voltage induced due to reluctance changes by armature movement. The oscillating movement of the armature will generate an AC voltage (V_{benf}). The direct or indirect detecting of this voltage can provide a measure for indicating movement of the solenoid armature.

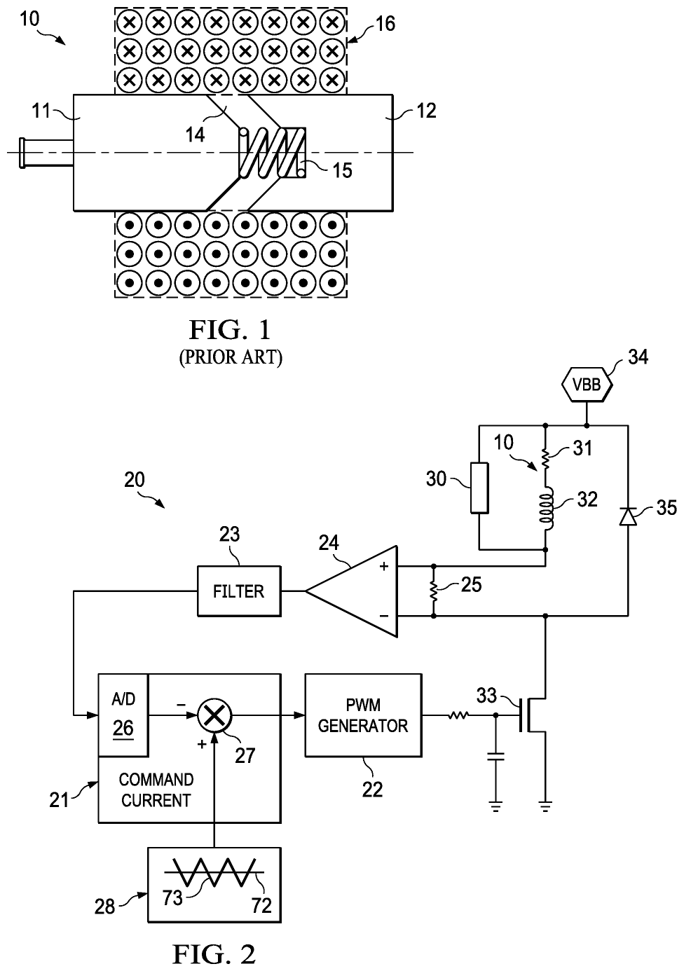

Referring to FIG. 2, a solenoid armature movement detecting system 20 is shown suitable for manufacturing as an integrated circuit using conventional integrated processes. The solenoid 10 is simplified as a resistor 31 in series with an inductor 32. The solenoid may be used in an automotive application for example to shift gears in the transmission or engage emission control subsystems. The electromagnetic force of a solenoid directly relates to the current, so using current drive other than voltage drive is optimal for many devices with solenoids. Many current drive integrated circuits, such as NCV7120 made by ON Semiconductor®, or TD1404AX made by Axiomatic Technologies®, can be used to drive the solenoid. The NCV7120 is a six-channel solenoid current controller with low-side predrivers for discrete N-FETs. The chip can be used in accurate current controlled solenoid applications. Each predriver channel contains a programmable PWM current controller with dithering modulation. The NCV7120 control registers are accessible via SPI.

A DC power supply 34 is connected to an outer terminal of resistor 31, and the outer terminal of inductor 32 is coupled to a switch element 33 controlling current through the solenoid, which is sensed by a current sense resistor 25. A freewheeling diode 35 paralleled with the solenoid eliminates the sudden voltage spike across the switch element 33 when it is switched off. Switching element 33 may include any type of mechanical or electrical switch such as, for example, a solid-state transistor type switch (e.g., FET switch, BJT switch, CMOS switch, IGBT switch, etc.), or any other device suitable for selectively coupling the power supply 34 to solenoid 10. Switching element 33 may be electronically operated by a PWM generator 22 which is controlled by an electronic control unit 21. The PWM generator 22 generates a PWM signal based on a PWM command signal representing a desired value of solenoid current.

The electronic control unit 21 may include any type of processor on which processes and methods consistent with the disclosed embodiments may be implemented. Electronic control unit 21 may include one or more hardware components such as, for example, a central processing unit (CPU), a random-access memory (RAM) module, a read-only memory (ROM) module, a nonvolatile memory storage, an analog-to-digital (A/D) converter 26 and a comparator 27. Electronic control unit 21 may also include one or more software components on a nonvolatile computer-readable medium such as, for example, computer executable instructions for performing methods consistent with certain disclosed embodiments.

The electronic control unit 21 controls the PWM generator 22 to generate a PWM signal based on command current signal representing a desired value of solenoid current through a closed-loop current feedback system. The voltage across current sense resistor 25, which is proportional to the current in the solenoid, is sampled by an amplifier 24, filtered by filter 23 and fed back to the A/D converter 26. The comparator 27 compare the feedback value with the command current signal which is generated by a current set unit 28. The difference between the feedback value and the desired current is than used to adjust the PWM command signal, so as to produce the exact value of desired solenoid current regardless of changes in input voltage and reluctance of the solenoid.

Referring to FIG. 2, the current set unit 28 sets an average solenoid input current 72 and an alternating dither current 73 superimposed on the average solenoid input current 72. The initial amplitude of the dither current 73 is selected such that it is insufficient to overcome static friction and won't cause the armature to move. Because of the closed-loop feedback arrangement, the waveform of the solenoid current will be substantially the same as the waveform from the current set unit 28, i.e., a superposition of the average solenoid input current 72 and the alternating dither current 73.

The average solenoid input current 72 is held fixed (e.g., at a value corresponding to a given armature position) and the amplitude of the dither current 73 is gradually increased from its initial value until the static friction is overcome and the armature becomes mobile. Note that the frequency of the dither current is preferably kept the same as the dither amplitude increases.

A voltage detecting unit 30 is used to detect the voltage across the solenoid. In some circumstance, there is no need for the voltage detecting unit 30, since the voltage across the solenoid can be calculated from the sensed current, knowledge of the supply voltage, and an equivalent circuit model of the solenoid; but for reduced complexity and enhanced robustness, use of a voltage detecting unit 30 may be preferred. The solenoid voltage signal produced by operation of the PWM generator 22 can be stored in the electronic control unit 21 and used to calculate a detection index voltage as explained in further detail below.

The dither signal drives the solenoid armature in a low-frequency micro-movement to eliminate the static friction. The amplitude of the dither signal is preferably related to the degree of friction force. The dither amplitude is preferably large enough to help the solenoid armature overcome the maximum static friction when the control signal (the average solenoid input current associated with a desired armature position) derivative is zero. If the dither amplitude is insufficient, micro-movement of the armature does not occur, which generally leads to hysteresis and poor performance. However, if the dither amplitude is too large, the armature may oscillate strongly, causing vibration of the solenoid, and in any case unnecessarily dissipating electrical power.

Solenoid vibration can be reduced by using a high enough dither frequency. Typical values are between 70 and 350 Hz for the dither frequency. If the frequency is too low, then the armature may not be able to follow the signal anymore due to stiction. However, if the dither frequency is too high, the mechanical inertia of the solenoid armature may cause it to respond poorly and perhaps lack sufficient movement to overcome static friction, thwarting the purpose of providing a dither signal. Therefore, the dither frequency should be within range for the signal to be effective (i.e., to cause micro-movements of the armature).

The PWM generator 22 generate a PWM signal to produce a solenoid current. In one embodiment, the PWM signal frequency is 2000 Hz, the average current I_{avg} for full pull-in is 300 mA, and the frequency of the dither current is 100 Hz. The current set unit 28 initially sets the amplitude of the dither current 73 at 5 mA, then step-by-step increases the amplitude of the dither current 73 until micro-movement of the solenoid armature is produced.

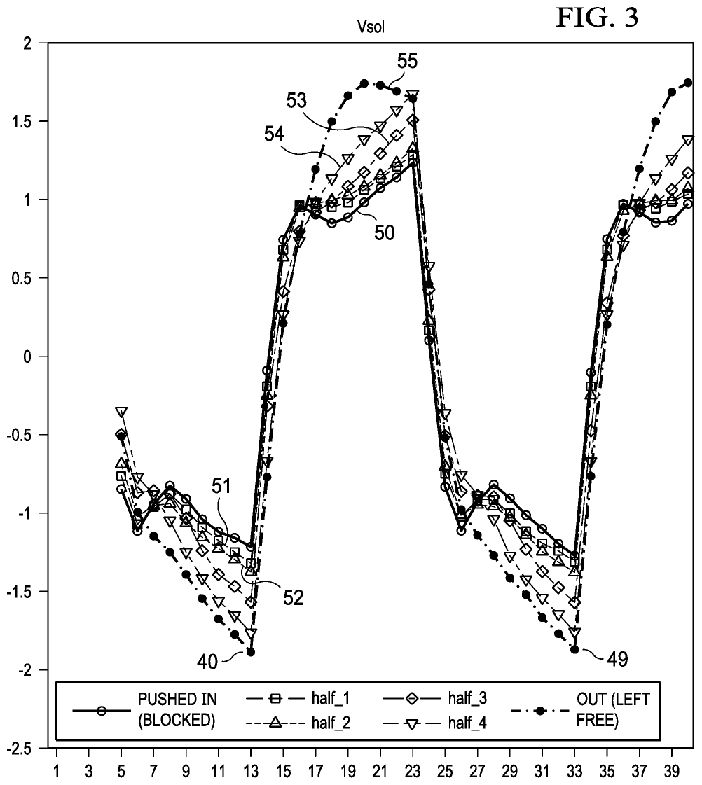

FIG. 3 shows the AC component of the voltage characteristics of an illustrative solenoid in different states when the average current of 300 mA is maintained by means of a 2 kHz PWM while a 100 Hz triangular dither current with amplitude of 150 mA peak to peak is added. The waveforms 50, 51, 52, 53, 54 and 55 show the AC component of the voltage characteristics when the solenoid is blocked (pushed in), very heavily loaded, heavily loaded, lightly loaded, nearly unloaded and unloaded (left free) respectively. The AC component of the voltage characteristic is fairly consistent for each of these loading conditions, it can be noticed that the peak to peak voltage increases when load decreases. Although the dither current has a triangular waveform in some of the example embodiments that are described herein, in some embodiments the dither current has other waveforms such as sine wave, trapezoidal, rectangular or saw tooth waveform.

The time span between point 40 and point 49 is a dither period. During half of the dither period, the current will increase linearly and during the other half of the dither period, the current will decrease linearly.

The R₀i component from equation (1) is not visible in FIG. 3 because the DC component of i is fixed to 300 mA and only the AC component is visible.

The

$$\frac{\partial ψ}{\partial i} \frac{d i}{dt}$$

component from equation (1) will be in this case resembling to a rectangular because the current is triangular. The rectangular voltage shape is smoothened a bit due to a filter-effect of the current control loop and a rounding effect at the current wave extrema. The

$$\frac{\partial ψ}{\partial δ} \frac{d δ}{dt}$$

component from equation (1) is approximating a sine-wave (when the armature is moving) with variable amplitude and -phase. As the amplitude of the sine-wave increases, the peak to peak voltage also increases. This deviation between waveforms indicates motion of the solenoid armature, enabling micro-movement to be detected from the solenoid voltage information.

Referring to FIG. 2, a method for detecting a micro-movement of the solenoid armature includes setting an average solenoid input current 72 and alternating dither currents 73 superimposed on the average solenoid input current 72 with a plurality of different amplitudes. The alternating dither currents 73 each preferably have the same frequency but different amplitudes. The amplitudes of the dither currents 73 are initially selected such that they are small enough to avoid moving the armature. The method further includes detecting for each of these small dither amplitudes the solenoid voltages (Vₛₒₗ). Based on the detected solenoid voltages, a detection index voltage (representing the solenoid voltage variation associated with the dither amplitude) can be calculated and used to determine if the solenoid armature starts to move.

In one embodiment, the detection index voltage is peak-to-peak variation of the average PWM voltage in a dither period (V_{PP}). The method to determine V_{PP} for a given dither amplitude includes calculating for each PWM period in the dither period the average voltage across the solenoid. PWM uses digital (“on/off”) pulses to create variable output currents for the solenoid. The pulses have constant amplitude, but their width is varied proportionally to the desired output amplitude. Each PWM period contains an “on” pulse and an “off” pulse. The width of the “on” pulse relative to the PWM period is called the PWM duty cycle (D) and can be expressed as an “on” percentage of the cycle. The PWM frequency is to determines how fast a cycle is finished.

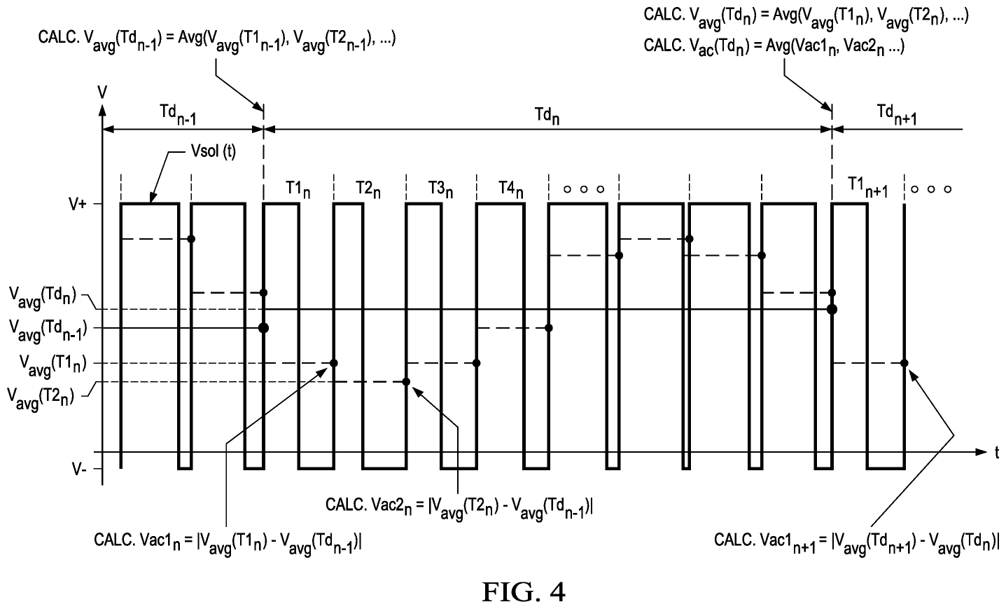

Referring to FIG. 4, a dither period Tdₙ includes a plurality of PWM periods T1ₙ, T2ₙ, . . . , The average voltage of any PWM period is V_{avg}=DV_{high}+(1−D)V_{low}, where V_{high} is the voltage when pulse is “on” and V_{low} is the applied voltage when the pulse is “off”, which are typically the maximum value of the source voltage and a recirculation voltage close to zero, respectively. In that case, the average voltage for PWM period T1ₙ can be expressed Vₐᵥ(T1ₙ)=D(T1ₙ)V_{high}, where D(T1ₙ) is the PWM duty cycle of T1ₙ period. (variation: a similar calculation if the recirculation voltage is not close to zero, e.g. when using fast decay). The solenoid voltage variation associated with the given dither amplitude can then be determined by finding, within each dither period, the maximum of the average PWM period voltages (Vmax), and the minimum of the average PWM period voltages (Vmin), and calculating the difference to obtain the peak-to-peak variation Vpp=Vmax−Vmin.

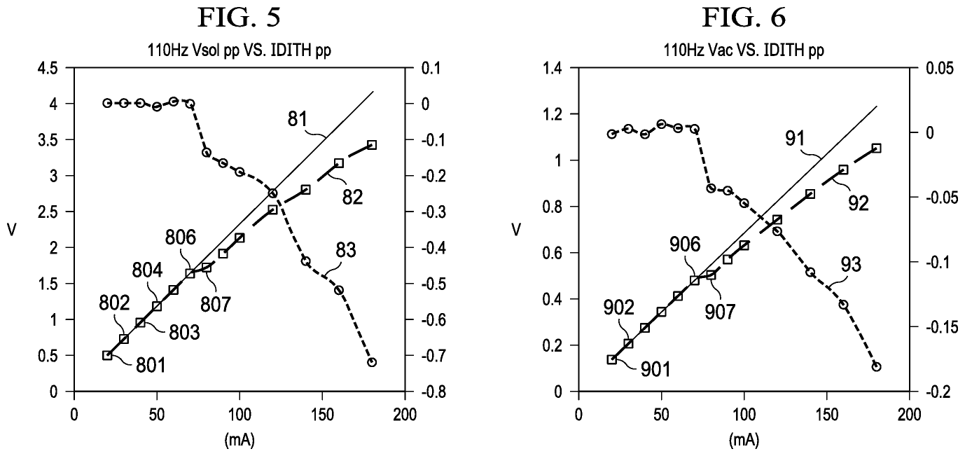

FIG. 5 shows the relationship between the dither amplitude I and the associated variation of solenoid voltage Vpp. The initial dither amplitudes, which are chosen to be insufficient to overcome static friction, correspond to point 801 and point 802, which may be used to determine a linear trend. At points 801, 802, the dither amplitudes and associated Vpp are (I₁,V₁) and (I₂,V₂), respectively. Using the interpolation method, the relationship between the dither amplitude I and Vpp can be expressed as a linear function:

$${V}_{p p} = {V}_{1} + \frac{{V}_{2} - {V}_{1}}{{I}_{2} - {I}_{1}} ( I - {I}_{1} ) \qquad ( 2 )$$

The number of parameter-determining points may be chosen to be larger than two, in which case the linear function represented by line 81 can be determined by linear regression using, e.g., the least squares method.

After determining the linear function, the dither amplitude is increased step by step while observing V_{PP} and comparing it with the extrapolated value from the linear function. Above a certain dither amplitude, V_{PP} will start to deviate significantly from the extrapolated values, indicating motion of the armature.

Referring back to FIG. 5, line 82 represents the relationship between observed Vpp and dither amplitude, line 83 shows the difference (using the axis labels on the right) between the observed V_{PP} and extrapolated value. From point 803 to point 806, the differences are close to zero, which means that the solenoid armature does not move as described above. From point 806 to point 807, there is an abrupt difference between the observed V_{PP} and extrapolated value, indicating motion of the armature. The difference signal exhibits a relatively steep transition enabling easy detection.

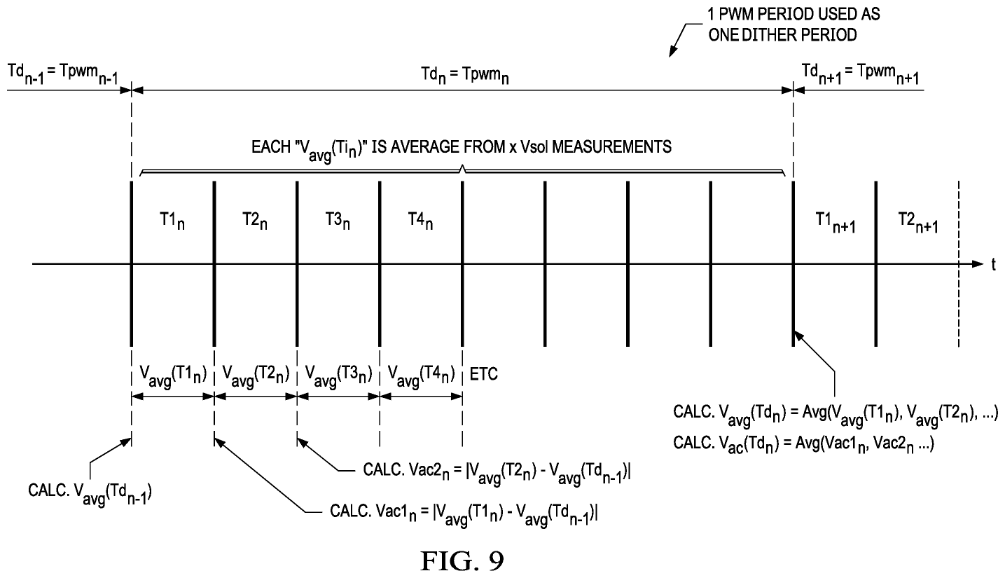

In another embodiment, the detection index voltage is an average rectified variation voltage V_{ac} in a calculation period. Referring back to FIG. 4, the “dither periods” Tdₓ may instead be taken to represent calculation periods, which are at least as long as a PWM period. (Compare with FIG. 9.) First an average voltage baseline is established by calculating the average solenoid voltage over a first calculation period, for example, over the calculation period Tdₙ₋₁. This average solenoid voltage may of course be determined by combining the average solenoid voltages for each PWM period in the first calculation period, e.g.,

V_{avg}(Tdₙ₋₁)=Avg(V_{avg}(T1ₙ₋₁),V_{avg}(T2ₙ₋₁), . . . ).

In the subsequent calculation period, the average solenoid voltage is determined for each PWM period and differenced with respect to the average voltage baseline from the preceding calculation period. The differences are rectified, e.g., for the T1ₙ PWM period, the rectified AC voltage is

V_{ac1n}=|V_{avg}(T1ₙ)−V_{avg}(Tdₙ₋₁)|.

The detection index voltage V_{ac} is then the average of the rectified AC voltages over the calculation period, e.g.,

V_{ac}(Tdₙ)=Avg(V_{ac1n},V_{ac2n}, . . . ).

This detection index voltage is an approximate measure of generated back EMF, i.e.,

V_{ac}=V_{bemf}+Vᵢᵥ,

where V_{bemf} is the back EMF voltage induced by an oscillating armature, and Vᵢᵥ represents the voltage required to generate dither current in solenoid inductance.

FIG. 6 shows the relationship between the dither amplitude I and solenoid voltage variation V_{ac}. Similar to FIG. 5, parameter determining point 901 and point 902 represent two amplitudes of dither current and associated V_{ac}. A linear function represented by line 91 between dither amplitude I and V_{ac} can be determined.

After determining the linear function, the dither amplitude is increased step by step while observing V_{ac} and comparing it with the extrapolated value based on linear function. Above a certain dither amplitude, V_{ac} will start to deviate significantly from the extrapolated value, indicating the armature has started to move. Line 92 represents the relationship between calculated V_{ac} and dither amplitude, line 93 shows the difference (using the scale on the right) between the calculated V_{ac} and extrapolated values. From point 902 to point 906, the differences are close to zero, indicating that the solenoid armature does not move and there is only the voltage required to generate dither current in solenoid inductance. From point 906 to point 907, there is an abrupt difference between the observed V_{ac} and extrapolated value, attributable to movement of the armature.

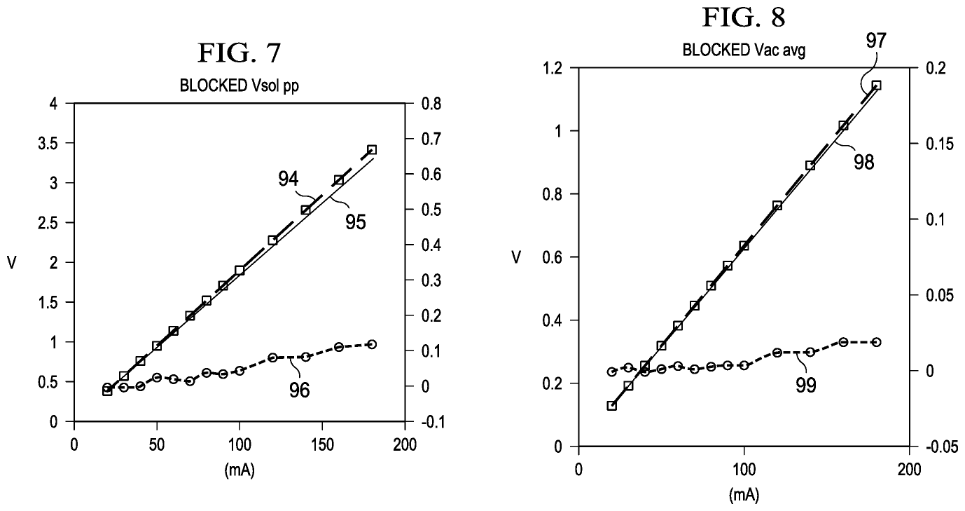

Solenoid voltage variations Vpp and V_{ac} can also be used to determine whether the solenoid armature is blocked. FIG. 7 shows the relationship between the dither amplitude I and Vpp when the solenoid armature is blocked. Line 94 represents the relationship between observed Vₚₚ and dither amplitude, line 95 represented a linear regression function between dither amplitude I and Vpp, line 96 shows the difference between the observed Vpp and extrapolated value relating to dither amplitude. Even when the dither amplitude I continues to increase beyond a value which is predicted to move the solenoid armature by a big margin, the differences keep close to zero, indicating that the solenoid armature does not move as described above.

Similarly, FIG. 8 shows the relationship between the dither amplitude I and V_{ac} when the solenoid armature is blocked. Line 97 represents the relationship between observed V_{PP} and dither amplitude, line 98 represented a linear regression function between dither amplitude I and Vpp, line 99 shows the difference between the observed V_{ac} and extrapolated value relating to dither amplitude. Even when the dither amplitude I continues to increase that exceeds a value which is predicted to move the solenoid armature by a big margin, the differences keep close to zero, indicating that the solenoid armature does not move.

In some instances, the PWM frequency is very low, and may even be equal to the dither frequency such one PWM period is equal to one dither period. This may be the case when the PWM current generates the dither current as a byproduct of the PWM process. In this situation, Vpp is not suitable, but V_{ac} can be obtained by means of a small adaptation of the calculation scheme as depicted hereafter.

Referring to FIG. 9, a calculating period Tdₙ includes a plurality of voltage averaging periods T1ₙ, T2ₙ, T3ₙ, . . . , which are smaller than the PWM periods. Determine the average solenoid voltage over a first calculating period, for example, over the calculating period Tdn−1 (The average solenoid voltage V_{avg}(Tdₙ₋₁)=Avg(V_{avg}(T1ₙ₋₁), V_{avg} (T2ₙ₋₁), . . . ),), to establish a baseline. The baseline is used in the next calculation period to determine a rectified AC voltage for each voltage averaging period, and the average of the rectified AC voltages in this calculation period, V_{ac}, can be used to determine if the solenoid armature starts to move. Over the calculating period Tdn, The average solenoid voltage V_{avg}(Tdₙ)=Avg(V_{avg}(T1ₙ),V_{avg}(T2ₙ), . . . ). Calculating for each dither period (in this case is equal to a PWM period and also equal to a calculating period) the rectified AC voltage, removing the DC component to build per x measurements (e.g. per voltage averaging period) the rectified AC waveform of the solenoid voltage while removing the DC component. For example, over T1ₙ voltage averaging period in the calculating period Tdn, the rectified AC voltage V_{ac1n}=|Vavg(T1n)−V_{avg}(Tdₙ₋₁)|; Calculating the average value (over a calculating period) of this rectified AC voltage to obtain V_{ac}, for example, over the calculating period of Tdn, V_{ac}(Tdₙ)=Avg(V_{ac1n},V_{ac2n}, . . . ).

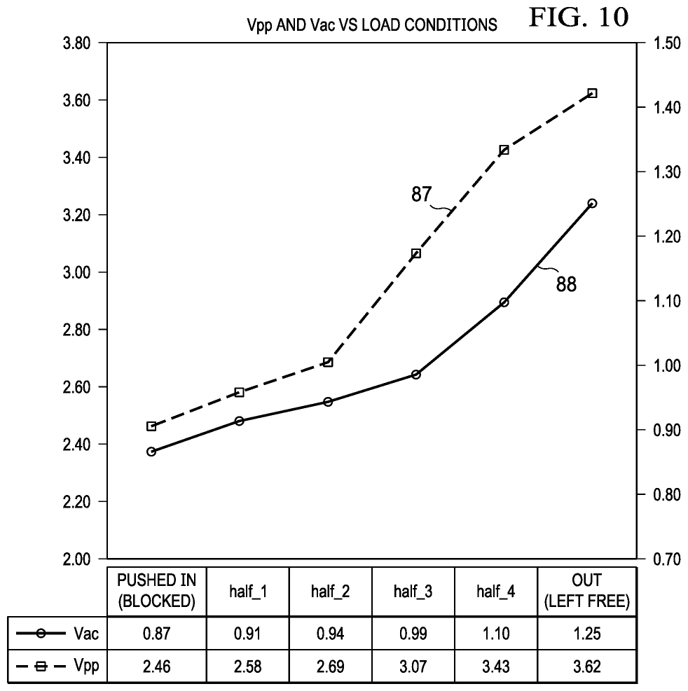

FIG. 3 indicates that the waveforms of the voltage of the solenoid are similar regardless that the solenoid is blocked, very heavily loaded, heavily loaded, lightly loaded, nearly unloaded or unloaded respectively. FIG. 10 shows how the detection index voltages are affected by different load conditions for the solenoid. Line 87 (using the left-side scale) and line 88 (using the right-side scale) represent the relationship between the Vpp, Vac and the load of the solenoid respectively. Regardless of the load, Vpp and Vac show similar trend relative to motion of armature. Therefore, Vpp and Vac can be used to detect the movement of the solenoid armature in different load conditions.

All of the compositions and methods disclosed and claimed herein can be made and executed without undue experimentation in light of the present disclosure. While the compositions and methods of this disclosure have been described in terms of preferred embodiments, it will be apparent to those of skill in the art that variations may be applied to the compositions and methods and in the steps or in the sequence of steps of the methods described herein without departing from the concept, spirit and scope of the disclosure. All such similar substitutes and modifications apparent to those skilled in the art are deemed to be within the spirit, scope and concept of the disclosure as defined by the appended claims.

What is claimed is:

1. A solenoid control method that comprises:
supplying a drive signal to a solenoid, the drive signal including:
an average current corresponding to a desired position of an armature; and
a dither current having a dither amplitude with an associated solenoid voltage variation;
varying the dither amplitude in a region insufficient to overcome static friction of the armature;
determining a linear relationship between the dither amplitude and the associated solenoid voltage variation in said region;
increasing the dither amplitude while monitoring the associated solenoid voltage variation for a deviation different from the voltage variation indicated by the linear relationship; and
upon detecting said deviation, employing a corresponding dither amplitude to maintain mobility of the armature.

2. The method of claim 1, wherein said drive signal is provided using PWM (pulse width modulation) at a PWM frequency.

3. The method of claim 2, wherein said dither frequency is less than the PWM frequency and a period of the dither current includes multiple PWM periods.

4. The method of claim 3, wherein said determining includes, for each of multiple dither amplitude values:
obtaining an average solenoid voltage for each PWM period in at least one period of the dither current; and
calculating said associated solenoid voltage variation based on a difference between a maximum and a minimum of the average solenoid voltages in the at least one dither period.

5. The method of claim 2, wherein a calculation frequency is less than the PWM frequency and a calculation period includes multiple PWM periods.

6. The method of claim 5, wherein said determining includes, for each of multiple dither amplitude values:
obtaining a baseline average solenoid voltage for a first calculation period;
obtaining for each PWM period in a subsequent calculation period an absolute value of a difference between the baseline average and an average solenoid voltage for that PWM period; and
calculating said associated solenoid voltage variation as an average of said absolute values.

7. The method of claim 1, wherein the dither current has a triangular, sine wave, trapezoidal, rectangular or saw tooth waveform.

8. The method of claim 1, further comprising: indicating that the armature is blocked if the dither amplitude reaches a predetermined threshold without detection of said deviation.

9. The method of claim 1, further comprising: repeating said varying, determining, and increasing operations each time the desired position changes.

10. A solenoid controller that comprises:
a PWM (pulse width modulation) driver that supplies a drive signal to a solenoid, the drive signal including:
an average current corresponding to a desired position of an armature; and
a dither current having a dither amplitude with an associated solenoid voltage variation;
a processor that controls the PWM driver to supply said drive signal, the processor implementing a control method that includes:
varying the dither amplitude in a region insufficient to overcome static friction of the armature;
determining a linear relationship between the dither amplitude and the associated solenoid voltage variation in said region;
increasing the dither amplitude while monitoring the associated solenoid voltage variation for a deviation different from voltage variation indicated by the linear relationship; and
upon detecting said deviation, employing a corresponding dither amplitude to maintain mobility of the armature.

11. The controller of claim 10, wherein the PWM driver supplies the drive signal via a switching element that selectively couples the solenoid coil to a power supply, and wherein the controller further includes a voltage sensor to detect the solenoid voltage.

12. The controller of claim 11, further comprising a current sensor for the drive signal to provide closed-loop feedback control.

13. The controller of claim 10, wherein said average current is provided using PWM at a PWM frequency, and said dither current is provided using a dither frequency less than the PWM frequency, with each period of the dither current including multiple PWM periods.

14. The controller of claim 13, wherein said determining includes, for each of multiple dither amplitude values:
obtaining an average solenoid voltage for each PWM period in at least one period of the dither current; and
calculating said associated solenoid voltage variation based on a difference between a maximum and a minimum of the average solenoid voltages in the at least one period.

15. The controller of claim 10, wherein said average current is provided using PWM at a PWM frequency, and said dither current is provided using a dither frequency, with each period of the dither current including less than two PWM periods, and wherein the processor performs said determining using a calculation period that includes multiple voltage averaging periods.

16. The controller of claim 15, wherein said determining includes, for each of multiple dither amplitude values:
obtaining a baseline average solenoid voltage for a first calculation period;
obtaining for each voltage averaging period in a subsequent period an absolute value of a difference between the baseline average and an average solenoid voltage for that voltage averaging period; and
calculating said associated solenoid voltage variation as an average of said absolute values.

17. The controller of claim 10, wherein the dither current has a triangular, sine wave, trapezoidal, rectangular or saw tooth waveform.

18. The controller of claim 10, wherein the control method further includes: indicating that the armature is blocked if the dither amplitude reaches a predetermined threshold without detection of said deviation.

19. The controller of claim 10, wherein the control method further includes: repeating said varying, determining, and increasing operations each time the desired position changes.

20. The controller of claim 10, the controller being implemented as an integrated circuit module.
